(19) United States
(12) Patent Application Publication
(10) Pub. No.: US 2017/0048470 A1
(43) Pub. Date: Feb. 16, 2017

(54) PIXEL CELL HAVING A RESET DEVICE WITH ASYMMETRIC CONDUCTION

(71) Applicants: Jorge Fernandez-Berni, Cordoba (ES); Michael Neimier, (US); Xiabobo Sharon Hu, (US); Ricardo Carmona-Galan, Seville (ES); Angel Rodriguez-Vasquez, Sevilla (ES)

(72) Inventors: Jorge Fernandez-Berni, Cordoba (ES); Michael Niemier, Granger, IN (US); Xiabobo Sharon Hu, Granger, IN (US); Ricardo Carmona-Galan, Sevilla (ES); Angel Rodriguez-Vazquez, Seville (ES)

(21) Appl. No.: 15/220,473

(22) Filed: Jul. 27, 2016

Related U.S. Application Data
(60) Provisional application No. 62/203,214, filed on Aug. 10, 2015.

(51) Int. Cl. H04N 5/355; H01L 27/146; H04N 5/353; H04N 5/374; H04N 5/378

(52) U.S. Cl. CPC H04N 5/3559; H04N 5/374; H04N 5/378; H04N 5/35581; H04N 5/3535; H01L 27/14643; H01L 27/14612

(57) ABSTRACT

Embodiments of the disclosure provide a solution to carry out High Dynamic Range (HDR) imaging based on dynamic well capacity adjustment without incurring additional spatial-temporal noise and consequent Signal-to-Noise Ratio (SNR) dips caused by the sub-threshold operation of a CMOS (Complementary Metal-Oxide-Semiconductor) reset transistor in a pixel cell. Embodiments of the disclosure employ realizations of transistors other than CMOS, e.g. Tunnel Field-Effect Transistors (TFETs), featuring asymmetric conduction between two of its terminals, where asymmetric conduction means that current can only flow in one direction between those two terminals. In some embodiments, one of such realizations plays the role of the pixel reset transistor in order to exploit the asymmetric conduction to perform dynamic well capacity adjustment. As a result, the sources of spatial-temporal noise arising from the sub-threshold operation of the pixel reset transistor in CMOS implementations are removed.

### CROSS-REFERENCE TO RELATED APPLICATIONS

This application claims the benefit of, and priority to, U.S. Provisional Application Ser. No. 62/203,214, filed Aug. 10, 2015, which is incorporated herein by reference in its entirety.

### STATEMENT REGARDING FEDERALLY SPONSORED RESEARCH OR DEVELOPMENT

This invention was made in part with Government support under grant no. 1344531, awarded by the National Science Foundation, and grant no. N00014-14-1-0355 awarded by the Office of Naval Research. The U.S. government has certain rights in the invention.

### BACKGROUND

CMOS (Complementary Metal-Oxide-Semiconductor) image sensors constitute a well-established technology finding applications in various massive markets, e.g. mobile phone cameras, automotive, medical imaging, surveillance . . . Still, noise and dynamic range are two major areas demanding further performance improvement in solid-state imaging.

Various techniques have been proposed to adapt the response of CMOS image sensors to different intra-scene lighting conditions, from low light levels to bright regions. This capability is commonly known as high dynamic range. Numerous performance trade-offs are involved in each of these techniques. Ideally, the highest possible dynamic range must be reached without impacting on two critical parameters of the sensor, namely pixel size and noise.

One of the better reported techniques in terms of large extension of the dynamic range with little impact on the pixel size is dynamic well capacity adjustment. It was originally applied in CCD (Charge-Coupled Device) image sensors. In CMOS, this technique presents a major disadvantage, namely the increase of both temporal and spatial noise on the pixel signal. This drawback is directly related to the sub-threshold operation of the reset transistor at the end of every adjustment of the well capacity during the photo-integration period. The temporal noise added from this sub-threshold operation is strongly dependent on CMOS technological parameters, in turn leading to high spatial variation of the pixel response, i.e. fixed pattern noise. The sub-threshold temporal noise also contributes to generate large dips in the signal-to-noise ratio.

### BRIEF DESCRIPTION OF THE DRAWINGS

FIG. 1 is a diagram of a three-transistor (3T) pixel cell (100) included within an image sensor array in accordance with an embodiment of the disclosure. Shown in FIG. 1 are a photodiode (106) together with a charge storage node (104); a buffering transistor (105); a switch transistor (107) connecting the pixel to the column output (108); and a reset device (103) with asymmetric conduction, that is, its gate control signal (102) can enable a current flowing only from the node (101) to the charge storage node (104).

FIG. 2 represents a graph of the current flowing through the pixel reset device with asymmetric conduction as a function of its terminal voltages (201), (202) and (203) in accordance with an embodiment of the disclosure.

FIG. 3 is a timing diagram (300) representing an exemplary temporal evolution of the signal at node (101) and its companion control signal (102) that can be applied on the pixel reset device with asymmetric conduction (103) in order to generate a pixel signal (104) featuring high dynamic range in accordance with an embodiment of the disclosure.

FIG. 4 is a block diagram showing an imaging system in accordance with an embodiment of the disclosure.

### SUMMARY

The present disclosure provides a pixel cell with the ability to carry out High Dynamic Range (HDR) imaging without the disadvantages found in current pixel cells. In one embodiment, the pixel cell comprises at least a reset device with asymmetric conduction and having at least three terminals. The first terminal can be connected to a tunable voltage source, the second terminal can be connected to the charge storage node, and the third terminal can control the flow of current from the first terminal into the second terminal.

In another embodiment, the present disclosure provides a method for obtaining a high-dynamic-range read-out signal from a pixel cell. The method can comprise first applying a reset pulse on the charge storage node through the reset device with asymmetric conduction in order to start the pixel data acquisition. The method can additionally comprise charge carriers being generated from radiation impinging on the photo-sensing element and stored on the charge storage node. The method can additionally comprise, after a first time interval of the photo-integration period, the voltage level at the first terminal of the reset device being decreased. The method can additionally comprise, after a second time interval of the photo-integration period, at least a second reset pulse being applied on the charge storage node through the reset device with asymmetric conduction. The method can additionally comprise charge carriers being again generated from radiation impinging on the photo-sensing element and stored on the charge storage node.

### DETAILED DESCRIPTION

Embodiments of the disclosure provide a solution to carry out High Dynamic Range (HDR) imaging based on dynamic well capacity adjustment without incurring additional spatial-temporal noise and consequent Signal-to-Noise Ratio (SNR) dips caused by the sub-threshold operation of a CMOS (Complementary Metal-Oxide-Semiconductor) reset transistor in a pixel cell.

Embodiments of the disclosure employ realizations of transistors other than CMOS, e.g. Tunnel Field-Effect Transistors (TFETs), featuring asymmetric conduction between two of its terminals, where asymmetric conduction means that current can only flow in one direction between those two terminals. In some embodiments, one of such realizations plays the role of the pixel reset transistor in order to exploit the asymmetric conduction to perform dynamic well capacity adjustment. As a result, the sources of spatial-temporal noise arising from the sub-threshold operation of the pixel reset transistor in CMOS implementations are removed.

It should be noted that, although the disclosure will be described below in connection with use in a three-transistor (3T) pixel cell, the disclosure has equal applicability to other pixel cell realizations, e.g. a four-transistor (4T) cell, where a transistor can be employed to partially remove photo-generated charge according to the level of impinging photon flux.

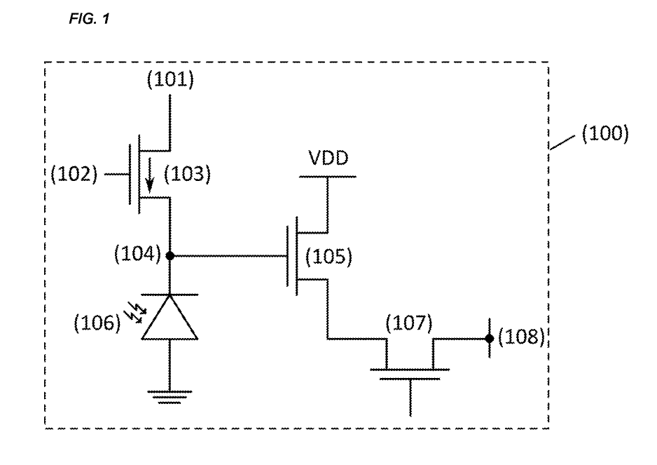

FIG. 1 is a diagram of a three-transistor (3T) pixel cell (100) included within an image sensor array in accordance with an embodiment of the disclosure. A pixel cell (100) includes: a light sensing element, e.g. a photodiode (106), together with its corresponding charge storage node (104); a source-follower transistor (105) buffering the pixel signal; a switch transistor (107) connecting the pixel to the column output (108); and a reset device (103) with asymmetric conduction, that is, its gate control signal (102) can enable a current flowing only from the node (101) to the charge storage node (104).

During operation, the charge storage node (104) is initially reset to a prescribed voltage by temporally asserting the digital gate control signal (102) of the reset device (103). Once (102) is de-asserted, the photo-integration period associated with an image capture starts. During this period, photo-generated electrons accumulate at the storage node (104), decreasing its voltage as electrons are negative charge carriers. The photo-generated charge can eventually exceed the capacity of the node (104) due to a high photon flux impinging the pixel. In order to adjust the response of the pixel to such a high photon flux, the voltage level at node (101) is first decreased. The gate control signal (102) is then temporally asserted again. Owing to the asymmetric conduction of the reset device (103), part of the charge accumulated at the storage node (104) will be removed if the voltage level at this node (104) is below the voltage level at node (101). Otherwise, the charge stored at node (104) remains unaffected. The gate control signal (102) is then de-asserted and photo-integration resumes. The adjustment of the pixel response by the method just described can be performed several times during the image capture. For each of these adjustments, the assertion of the gate control signal (102) is preceded by a decrease of the voltage level at node (101). The pixel data acquisition ends when the switch transistor (107) is turned on. The pixel voltage at the storage node (104) is then buffered by the source-follower transistor (105) and conveyed to the column output (108) for read-out.

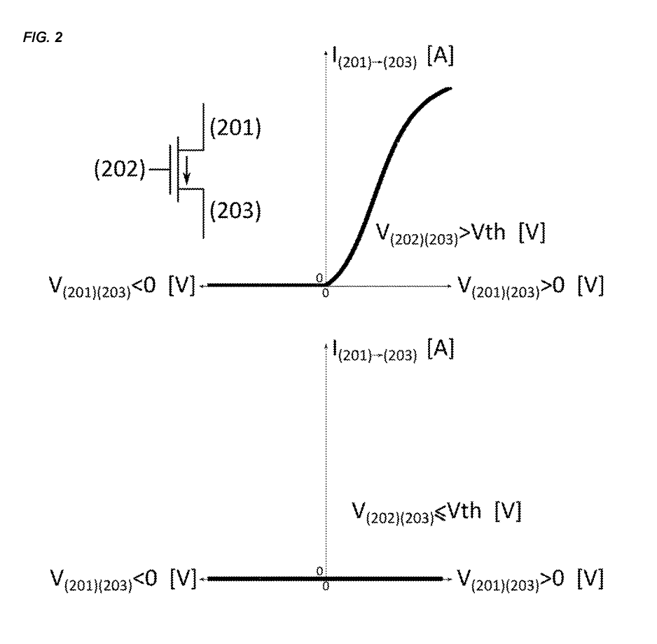

FIG. 2 represents a graph of the current flowing through the pixel reset device with asymmetric conduction as a function of its terminal voltages (201), (202) and (203) in accordance with an embodiment of the disclosure. The only substantial current flowing through the device takes place when the voltage between the terminals (202) and (203) exceeds an arbitrary threshold voltage Vth and the voltage at the terminal (201) is greater than the voltage at the terminal (203). Otherwise, the current flowing through the device is negligible in practical terms for the purpose of adapting the response of the pixel cell to the level of impinging photon flux as previously described.

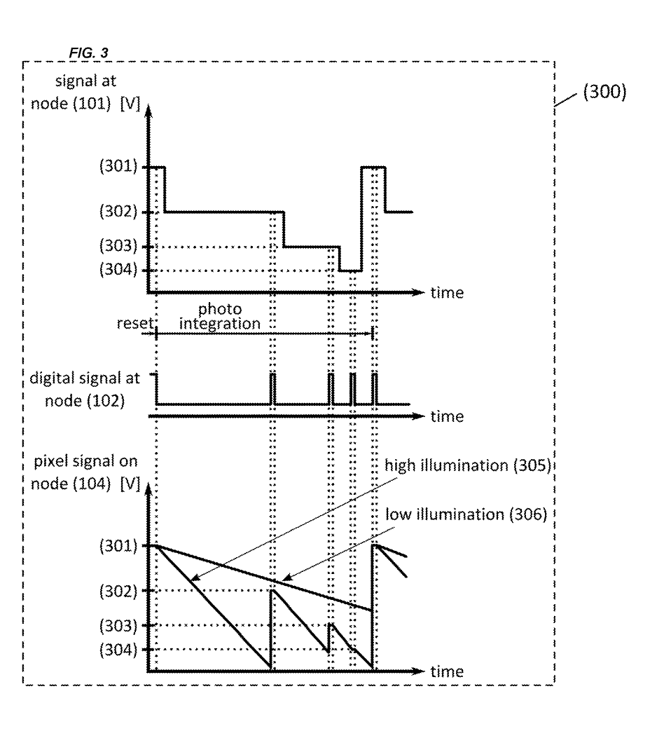

FIG. 3 is a timing diagram (300) representing an exemplary temporal evolution of the signal at node (101) and its companion digital control signal (102) that can be applied on the pixel reset device with asymmetric conduction in order to generate a pixel signal (104) featuring HDR in accordance with an embodiment of the disclosure. Once the charge storage node is reset to the voltage level (301), the digital gate control signal (102) is de-asserted in order to start photo-integration. The signal at node (101) is then set to a new voltage (302) below (301). When the control signal (102) is asserted again, the first adjustment of the accumulated charge takes place. For highly illuminated pixels (305) whose pixel voltage (104) gets below the adjustment level (302), part of the photo-generated charge is removed by the current injected through the reset device. On the contrary, low illuminated pixels (306) whose pixel voltage (104) keeps above the level (302) remain unaffected due to the asymmetric conduction of the reset device. Two more adjustments like this take place at voltage levels (303) and (304) respectively before a new pixel data acquisition is initiated by resetting the charge storage node to the voltage level (301) again.

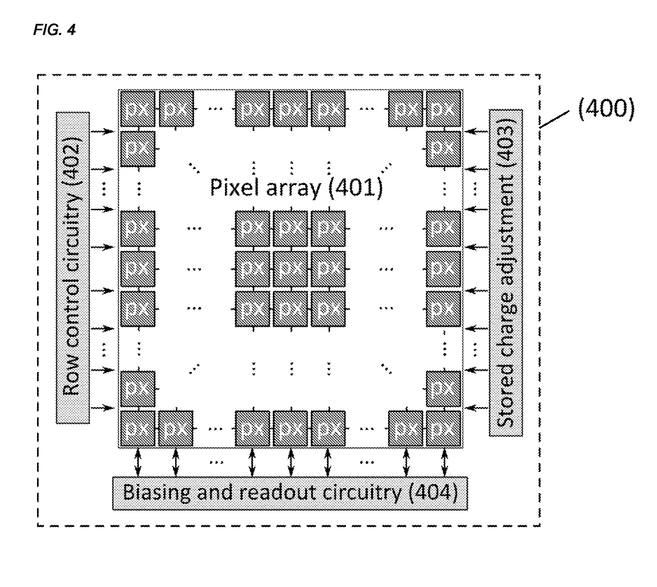

FIG. 4 is a block diagram showing an imaging system in accordance with an embodiment of the disclosure. The illustrated embodiment (400) includes pixel array (401), row control circuitry (402), circuitry for stored charge adjustment (403), and column biasing and read-out circuitry (404).

Pixel array (401) is a two-dimensional (2D) array of pixel cells. In one embodiment, all of the pixel cell transistors are CMOS devices except for the reset transistor, which is realized by a different combination of solid-state materials in order to give rise to asymmetric conduction in the aforementioned terms. In another embodiment, only some of the pixel cell transistors are CMOS devices. Yet in another embodiment, no CMOS transistor is present at the pixel cell. Pixel array (401) may be implemented as a front-side illuminated sensor or as a back-side illuminated sensor.

Circuitry for stored charge adjustment (403) generates the gate control signal (102) and the signal at node (101) during image capture in order to exploit the asymmetric conduction of the reset device for fitting the pixel response to the impinging photon flux. In one embodiment, signals (101) and (102) are generated by circuitry (403) as rolling shutter signals for the progressive acquisition of the image pixel data. In another embodiment, signals (101) and (102) are generated by circuitry (403) as global shutter signals for the simultaneous acquisition of the entire image pixel data. Row control circuitry (402) and column biasing and read-out circuitry (404) operate jointly for the activation of the switch transistor (107) and subsequent read-out of the column output (108) respectively. Column biasing and read-out circuitry (404) may include amplification circuitry, correlated double sampling circuitry, analog-to-digital conversion or otherwise.

What is claimed is:

1. A pixel cell comprising a reset device with asymmetric conduction having at least three terminals, the first terminal being connected to a tunable voltage source, the second terminal being connected to a charge storage node, and the third terminal controlling current flowing from the first terminal into the second terminal.

2. The pixel cell of claim 1, further comprising: a photo-sensing element, a buffering transistor and a read-out transistor.

3. The pixel cell of claim 1, wherein current flows from the first terminal of the reset device to the second terminal of the reset device when a difference in voltage between the third and second terminals of the reset device exceeds a threshold voltage, and when voltage at the first terminal of the reset device exceeds voltage at the second terminal of the reset device.

4. The pixel cell of claim 3, wherein any other combinations of voltages across the terminals of the reset device give rise to negligible levels of current flowing between the terminals of the reset device.

5. A method for obtaining a high-dynamic-range read-out signal from the pixel cell of claim 1, the method comprising the steps of first applying a reset pulse on the charge storage node through the reset device with asymmetric conduction in order to start the pixel data acquisition; charge carriers being then generated from radiation impinging on the photo-sensing element and stored on the charge storage node; after a first time interval of the photo-integration period, the voltage level at the first terminal of the reset device being decreased; after a second time interval of the photo-integration period, at least a second reset pulse being applied on the charge storage node through the reset device with asymmetric conduction; charge carriers being again generated from radiation impinging on the photo-sensing element and stored on the charge storage node.

6. The method of claim 5, wherein a plurality of reset pulses is applied on the charge storage node throughout the photo-integration period.

7. The method of claim 5, wherein each reset pulse applied on the charge storage node during the photo-integration period can remove part of the charge accumulated at the charge storage node depending on the combinations of voltages across the terminals of the reset device with asymmetric conduction.

8. The method of claim 5, further comprising the step of enabling the read-out of the pixel signal at the charge storage node by switching on the read-out transistor resulting in the pixel signal being buffered by the buffering transistor and the buffered pixel signal being conveyed to the column output.

9. The method of claim 5, wherein the signals related to the application of the reset pulses are generated by circuitry for stored charge adjustment located at the periphery of an array of pixel cells.
